(19) United States
(12) Patent Application Publication
(10) Pub. No.: US 2024/0266213 A1
(43) Pub. Date: Aug. 8, 2024

(54) Semiconductor Device and Method of Forming the Same

(71) Applicant: MICRON TECHNOLOGY, INC., BOISE, ID (US)

(72) Inventor: YASUHIRO MAMETSUKA, Hiroshima (JP)

(73) Assignee: MICRON TECHNOLOGY, INC., Boise, ID (US)

(21) Appl. No.: 18/514,125

(22) Filed: Nov. 20, 2023

Related U.S. Application Data
(60) Provisional application No. 63/482,951, filed on Feb. 2, 2023.

(51) Int. Cl. H01L 21/768; H01L 23/528; H01L 23/532; H10B 12/00

(52) U.S. Cl. CPC H01L 21/7682; H01L 23/528; H01L 23/53266; H10B 12/0335; H10B 12/482

(57) ABSTRACT

An apparatus includes: first and second conductive pillars in a first layer, each of the first and second conductive pillars including a conductive plug of which a first side surface is covered with a barrier material and a second side surface opposed to the first side surface is coupled to an air-gap free from the barrier material; a wiring in the first layer, the wiring arranged between the first conductive pillar and the second conductive pillar such that a first side surface of the wiring faces to the barrier metal of the first conductive pillar and a second side surface opposed to the first side surface of the wiring faces to the air-gap of the second conductive pillar.

### CROSS REFERENCE TO RELATED APPLICATION(S)

This application claims priority to U.S. Provisional Application No. 63/482,951, filed Feb. 2, 2023. The aforementioned application is incorporated herein by reference, in its entirety, for any purpose.

### BACKGROUND

In recent years, semiconductor devices exemplified by dynamic random access memories (DRAMs) have been desired to have increased memory capacity, and the memory capacity has been increased by fining processing dimensions. However, as the memory capacity increases, the wiring capacity tends to increase.

### BRIEF DESCRIPTION OF THE DRAWINGS

FIG. 1 is a plan view showing a schematic layout configuration of a part of a semiconductor device according to an embodiment.

FIG. 2 is a longitudinal sectional view showing a schematic configuration of a part of the semiconductor device according to the embodiment, and also is a longitudinal sectional view schematically showing a portion taken along line A-A of FIG. 1.

FIG. 3 is a circuit diagram showing a schematic configuration of an equivalent circuit of a memory cell of the semiconductor device according to the embodiment.

FIGS. 4A to 9B are diagrams showing a method of forming the semiconductor device according to the embodiment, and are longitudinal sectional views showing schematic configurations of the semiconductor device at exemplary process stages, where FIGS. 4B, 5B, 6B, 7B, 8B, and 9B are longitudinal sectional views schematically showing the portion taken along line A-A in FIG. 1A, and FIGS. 4C, 5C, 6C, and 8C are cross-sectional views schematically showing portions taken along line B-B of FIGS. 4B, 5B, 6B, and 8B, respectively.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

A semiconductor device according to an embodiment and a method of forming the same will be described hereunder with reference to the drawings. In the following description, a dynamic random access memory (DRAM) will be exemplified and described as a semiconductor device. In the description of the present embodiment, common or related components or substantially the same components are denoted by the same reference signs, and duplicative description thereof is omitted. In the following drawings, the dimensions and dimensional ratios of the respective portions in the respective drawings do not necessarily match the dimensions and dimensional ratios in the embodiment. Further, in the following description, a Y direction is perpendicular to an X direction. A Z direction is perpendicular to an X-Y plane which is the plane of a semiconductor substrate, and is sometimes referred to as a vertical direction.

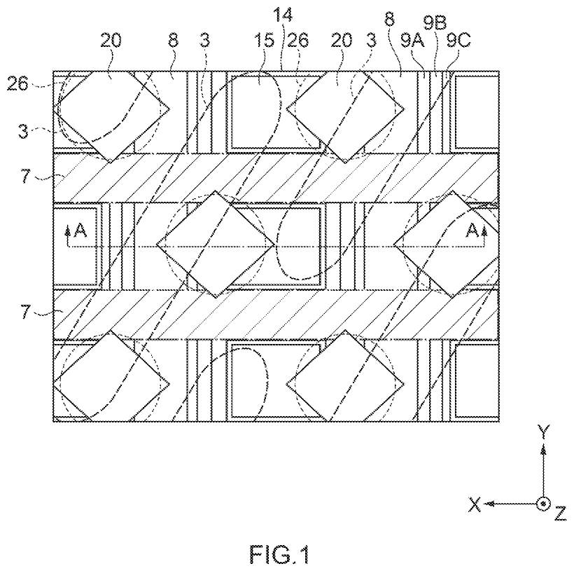

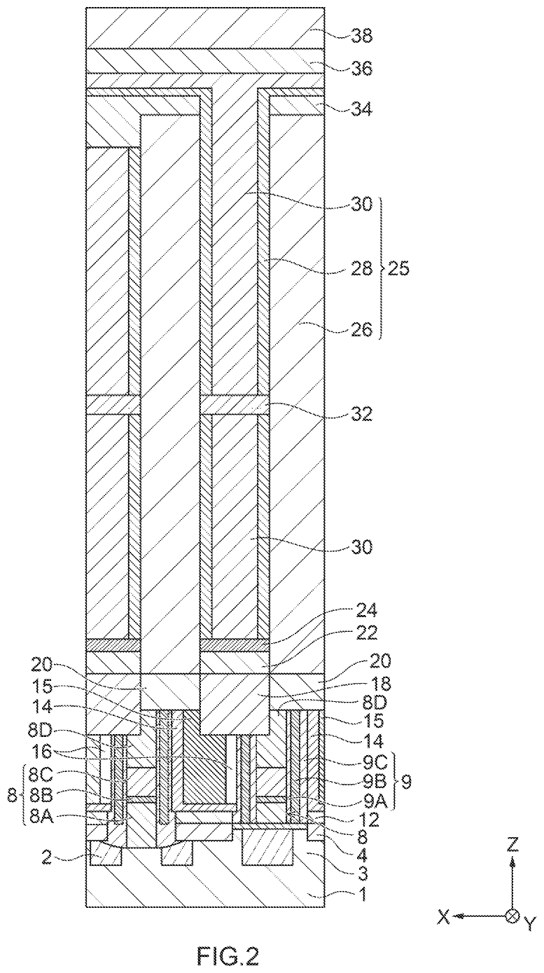

The semiconductor device according to the present embodiment will be described hereunder. FIGS. 1 and 2 show a configuration of a memory cell portion of the semiconductor device which is formed on a semiconductor substrate 1. As shown in FIGS. 1 and 2, isolations 2, active regions 3, word-lines 7, bit-lines 8, and cell capacitors 25 are provided on the semiconductor substrate 1. The semiconductor substrate 1 includes, for example, a disc-shaped single-crystal silicon wafer having a mirror-finished principal plane.

As shown in FIG. 1, each of a plurality of word-lines 7 extends in the X direction. The plurality of word-lines 7 are arranged in parallel with a predetermined pitch in the Y direction. Each of a plurality of bit-lines 8 extends in the Y direction. The plurality of bit-lines 8 are arranged in parallel with a predetermined pitch in the X direction. The word-lines 7 and bit-lines 8 intersect each other. Each of a plurality of active regions 3 has an island shape extending obliquely from the upper right to the lower left in FIG. 1.

The bit-line 8 intersects the active region 3 at the center portion of the active regions 3. Bit-line sidewall insulating films 9 are provided on the side surface of the bit-line 8, and the bit-line sidewall insulating film 9 includes a first bit-line sidewall insulating portion 9A, a second bit-line sidewall insulating portion 9B, and a third bit-line sidewall insulating portion 9C. A conductive plug 15 is arranged at an edge portion of the active region 3. A barrier material 14 covers the bottom and side surface of the conductive plug 15. The barrier metal 14 and the conductive plug 15 have a pillar shape, and function as a cell contact of DRAM.

A rectangular pad conductive portion 20 is connected to one end portions of the barrier metal 14 and the conductive plug 15 in the X direction. A capacitor lower electrode 26 is connected to an upper portion of the pad conductive portion 20. As shown in FIG. 2, a first interlayer insulating film 18 is arranged at the other end portion of the pad conductive portion 20 in the X direction.

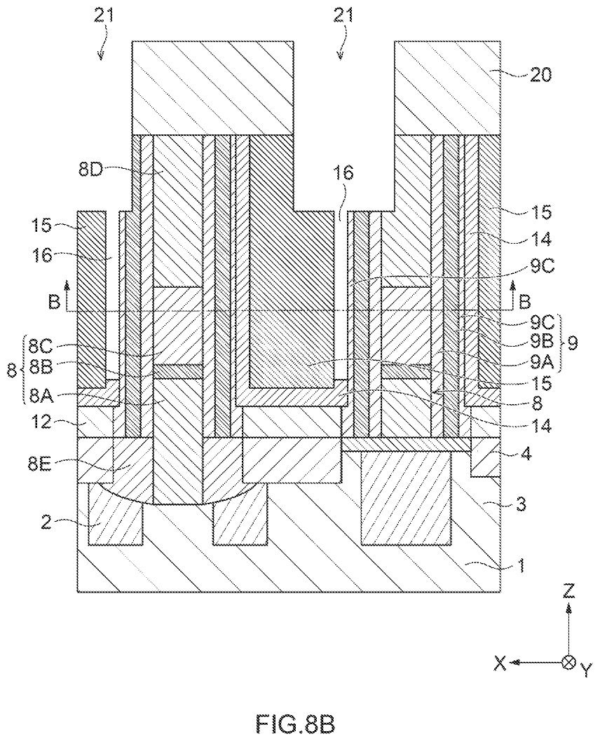

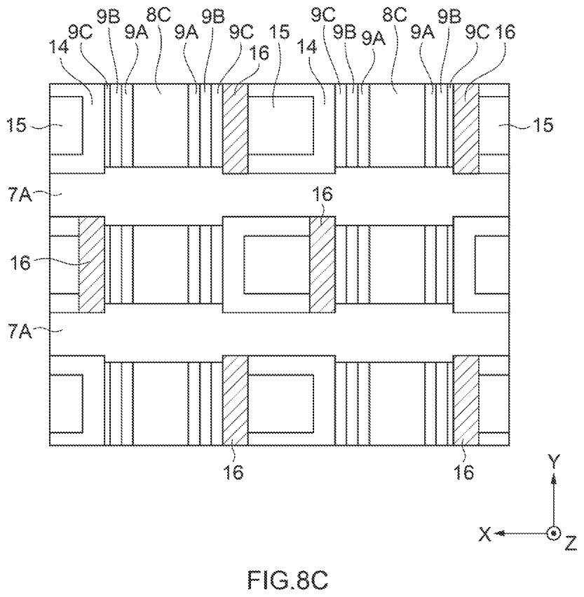

The first interlayer insulating films 18 are alternately arranged on the left and right sides of the bit-line 8 in a staggered arrangement. As shown in FIG. 2 described later, air-gaps 16 are arranged under the first interlayer insulating films 18. As shown in FIG. 8C described later, the air-gaps 16 are also alternately arranged on the left and right sides of the bit-line 8 in a staggered arrangement. The pad conductive portion 20 is arranged on the first bit-line sidewall insulating portion 9A, the second bit-line sidewall insulating portion 9B, and the third bit-line sidewall insulating portion 9C in an opposite direction of the air-gap 16 in the X direction. The air-gap 16 is provided between it the bit-line sidewall insulating film 9 and the conductive plug 15.

As shown in FIG. 2, the isolations 2 include an insulating material buried in trenches formed in the semiconductor substrate 1. The isolations 2 surround the active regions 3. The active regions 3 are defined by the isolations 2. The active regions 3 are doped with impurities such as phosphorus (P), arsenic (As), and boron (B), or the like, and the active regions 3 have electrical conductivity. The active regions 3 serve as source/drain regions of access transistors 142. An insulating material such as silicon dioxide or silicon nitride is embedded in the isolations 2.

The bit-line 8 includes a first bit-line conductive portion 8A, a second bit-line conductive portion 8B, and a third bit-line conductive portion 8C in order from the semiconductor substrate 1 side, and includes a bit-line upper insulating portion 8D on the third bit-line conductive portion 8C. The first bit-line conductive portion 8A includes polysilicon doped with impurities such as phosphorus, arsenic or boron. The second bit-line conductive portion 8B includes an electrically conductive material such as titanium nitride (TiN). The third bit-line conductive portion 8C includes an electrically conductive material such as tungsten (W). The bit-line upper insulating portion 8D includes an insulating material such as silicon nitride (SiN).

The first bit-line sidewall insulating portion 9A, the second bit-line sidewall insulating portion 9B, and the third bit-line sidewall insulating portion 9C are arranged on sidewalls of the bit-line 8 and the bit-line upper insulating portion 8D, and the conductive plug 15 and the barrier metal 14 as a conductive plug are arranged on the side surface thereof. The barrier metal 14 covers the bottom and side surfaces of the conductive plug 15. A first conductive portion 4 is arranged under the barrier metal 14, and the first conductive portion 4 is connected to the active region 3. The barrier metal 14 and the conductive plug 15 form one pillar-shaped cell contact electrode.

The first bit-line sidewall insulating portion 9A includes, for example, silicon carbonitride (SiOC). The second bit-line sidewall insulating portion 9B includes, for example, silicon oxide (SiOx). The third bit-line sidewall insulating portion 9C includes, for example, silicon nitride. The barrier metal 14 includes, for example, a laminated film of titanium (Ti) and titanium nitride. The barrier metal 14 functions as a barrier for preventing the conductive plug 15 and an under-cell-contact conductive portion 12 from directly contacting each other. The conductive plug 15 includes, for example, tungsten. The first conductive portion 4 is arranged below the under-cell-contact conductive portion 12. The first conductive portion 4 includes, for example, polysilicon doped with impurities such as phosphorus, arsenic, or boron.

The air-gap 16 is arranged between the first bit-line sidewall insulating portion 9A and the conductive plug 15 on one side surface in the X direction of the bit-line 8. The air-gap 16 includes a hollow. The existence of the air-gap 16 reduces the capacitance value between the bit-line 8 and the conductive plug 15. As a result, the bit-line capacitance is reduced, so that it is possible to increase the operating speed of the semiconductor device according to the embodiment.

The cell capacitor 25 includes a capacitor lower electrode 26, a capacitor insulating film 28, and a capacitor upper electrode 30. The conductive plug 15 is connected to the pad conductive portion 20 on the upper surface thereof, and the pad conductive portion 20 is connected to the capacitor lower electrode 26 on the upper surface thereof. As a result, the capacitor lower electrode 26 is electrically connected to the active region 3.

An on-capacitor insulating portion 34 is arranged on the capacitor lower electrode 26. The capacitor insulating film 28 is arranged so as to cover the capacitor lower electrode 26 and the on-capacitor insulating portion 34. The capacitor upper electrode 30 is arranged so as to cover the side and upper surfaces of the capacitor insulating film 28. The capacitor lower electrode 26 contains a conductive material, for example, titanium nitride. The on-capacitor insulating portion 34 contains an insulating material, for example, silicon nitride. The capacitor insulating film 28 contains an insulating material, for example, zirconium oxide (ZrOx). The capacitor upper electrode 30 contains a conductive material, for example, titanium nitride.

A first top cell conductive portion 36 and a second top cell conductive portion 38 are arranged on the capacitor upper electrode 30. The first top cell conductive portion 36 and the second top cell conductive portion 38 function as a plate electrode of DRAM. The first top cell conductive portion 36 covers the upper surface of the capacitor upper electrode 30, and the second top cell conductive portion 38 covers the upper surface of the first top cell conductive portion 36. The first top cell conductive portion 36 contains a conductive material, for example, polysilicon doped with impurities such as phosphorus, arsenic or boron. The second top cell conductive portion 38 contains a conductive material, for example, tungsten.

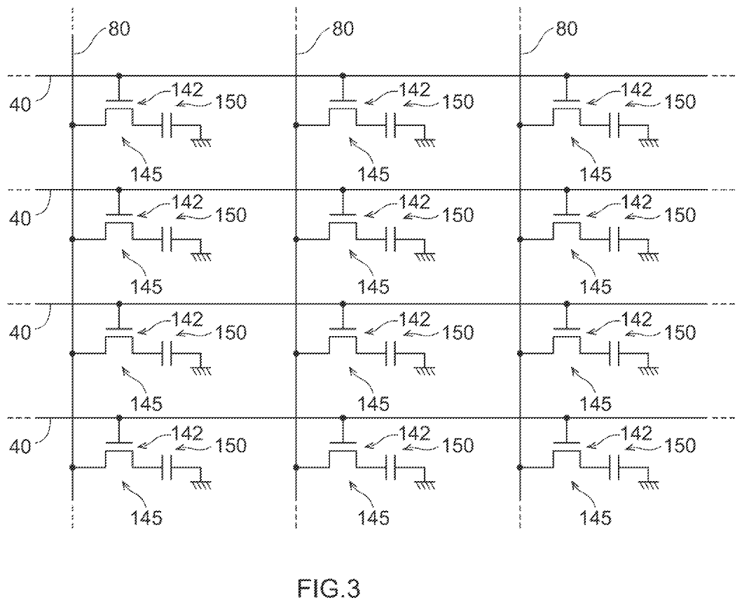

Next, an equivalent circuit of the memory cell array of the semiconductor device according to the present embodiment will be described with reference to FIG. 3. In FIG. 3, word-lines 40 and bit-lines 80 correspond to the word-lines 7 and the bit-lines 8 described above. Storage capacitors 150 correspond to the cell capacitors 25.

FIG. 3 shows an equivalent circuit of the memory cell array of the semiconductor devices according to the present embodiment. A plurality of memory cells 145 are arranged in a matrix form while the memory cells 145 are connected to respective intersections between pluralities of word-lines 40 and bit-lines 80 which are arranged orthogonally. One memory cell 145 includes a pair of the access transistor 142 and the storage capacitor 150.

The access transistor 142 includes, for example, a MOSFET. The gate electrode of the access transistor 142 functions as a word-line 40 of the DRAM. The word-line 40 functions as a control line for controlling selection of corresponding memory cells. One of the source/drain of the access transistor 142 is connected to the bit-line 80, and the other is connected to the storage capacitor 150. The storage capacitor 150 includes a capacitor, and data is stored by accumulating charges in the capacitor.

When writing data into the memory cell 145, a potential for setting the access transistor 142 to ON is applied to the word-line 40, and a low potential or a high potential corresponding to write data “0” or “1” is applied to the bit-line 80. When reading data from the memory cell 145, a potential for setting the access transistor 142 to ON is applied to the word-line 40. As a result, a potential drawn from the storage capacitor 150 to the bit-line 80 is sensed by a sense amplifier connected to the bit-line 80, thereby determining the data.

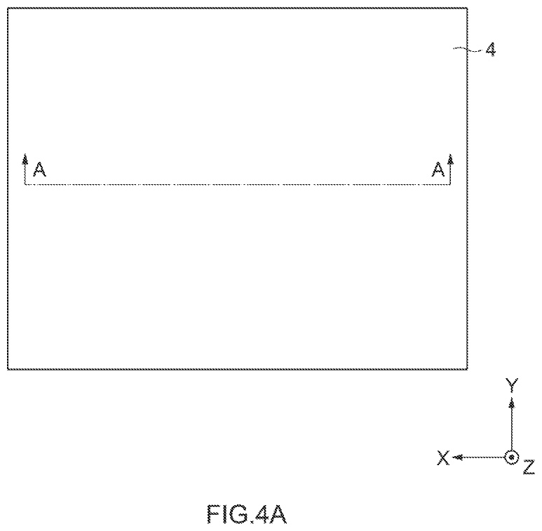

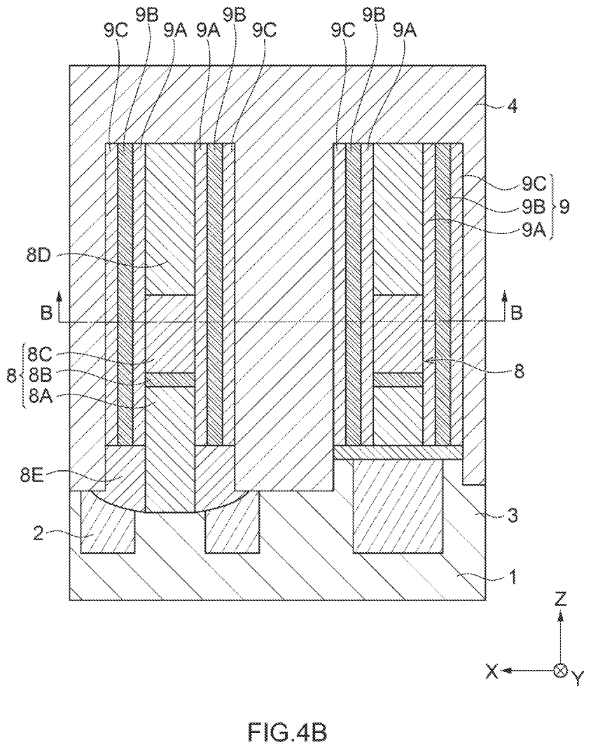

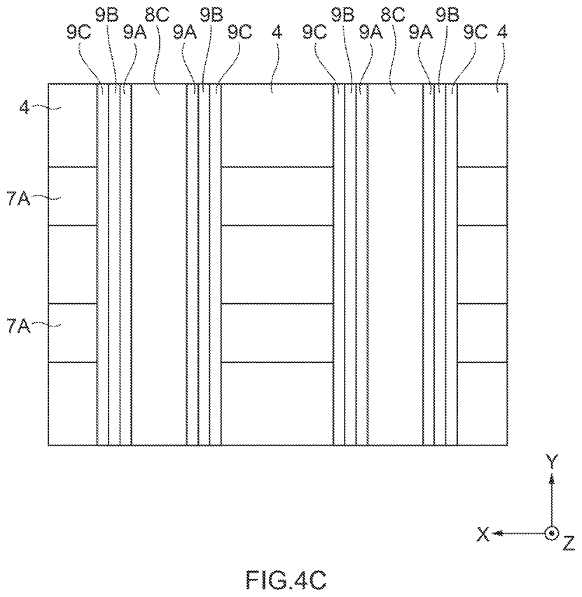

Next, a method of forming the semiconductor device according to the embodiment will be described. As shown in FIGS. 4A, 4B and 4C, the isolations 2, the active regions 3, the bit-lines 8, the bit-line upper insulating portions 8D, the first bit-line sidewall insulating portions 9A, the second bit-line sidewall insulating portions 9B, the third bit-line sidewall insulating portions 9C, and the first conductive portion 4 covering the upper portions thereof are formed on the semiconductor substrate 1. FIG. 4C shows word-line upper insulating portions 7A provided on the word-lines 7. The word-line upper insulating portions 7A contain silicon nitride, for example.

The bit-lines 8 and the bit-line upper insulating portions 8D are formed by forming a film of an insulating material such as silicon dioxide and then patterning the film using known lithographic technique and anisotropic dry etching technique. Further, the first bit-line sidewall insulating portions 9A, the second bit-line sidewall insulating portions 9B, and the third bit-line sidewall insulating portions 9C are formed by forming a film of an insulating material such as silicon dioxide or silicon nitride, and then performing etch back using an anisotropic dry etching technique.

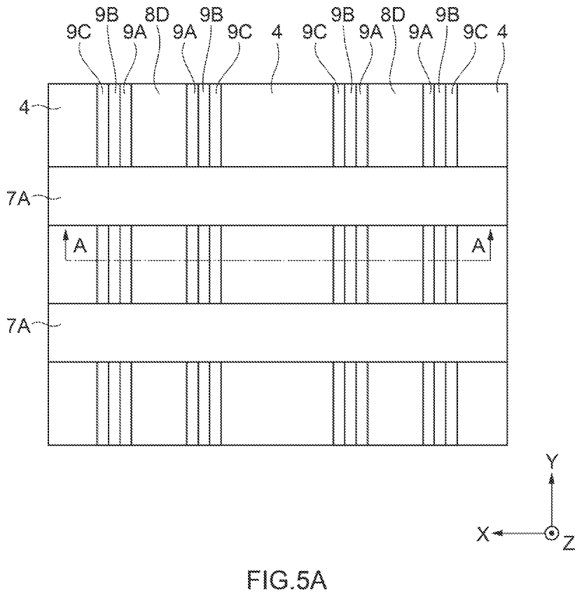

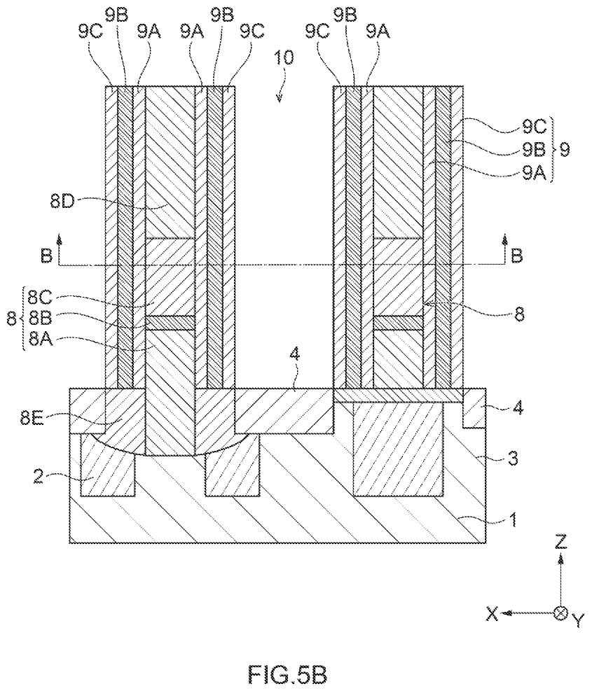

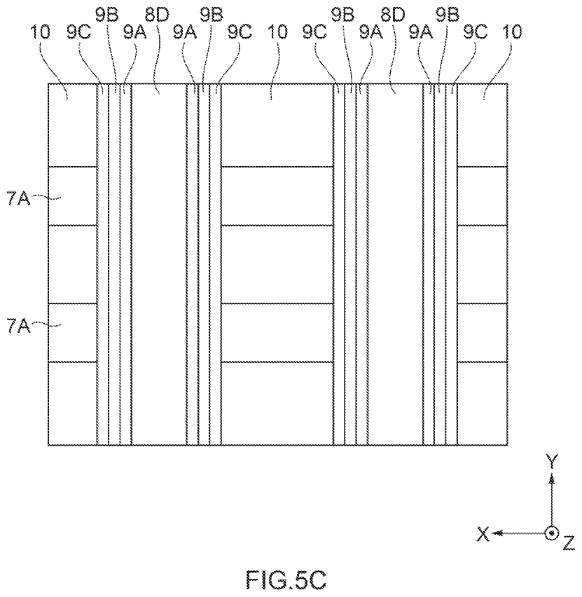

Next, as shown in FIGS. 5A, 5B and 5C, the first conductive portion 4 is etched back using an anisotropic dry etching technique to leave only a part of the bottom portion of the first conductive portion 4. Through this processing, a recess portion 10 is formed between the bit-line 8 and the bit-line upper insulating portion 8D.

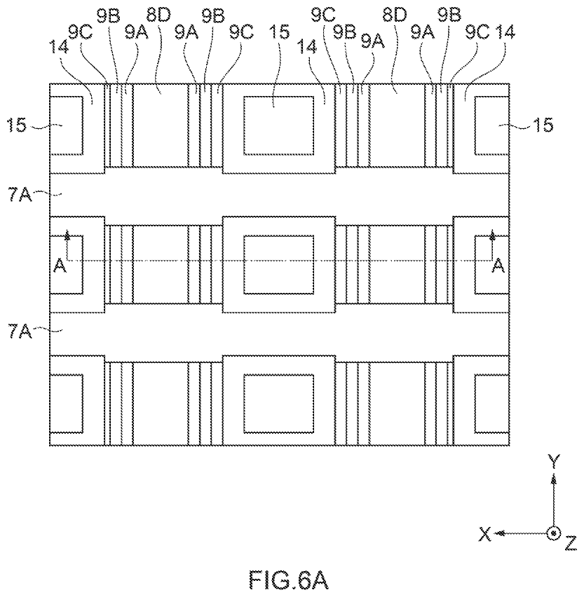

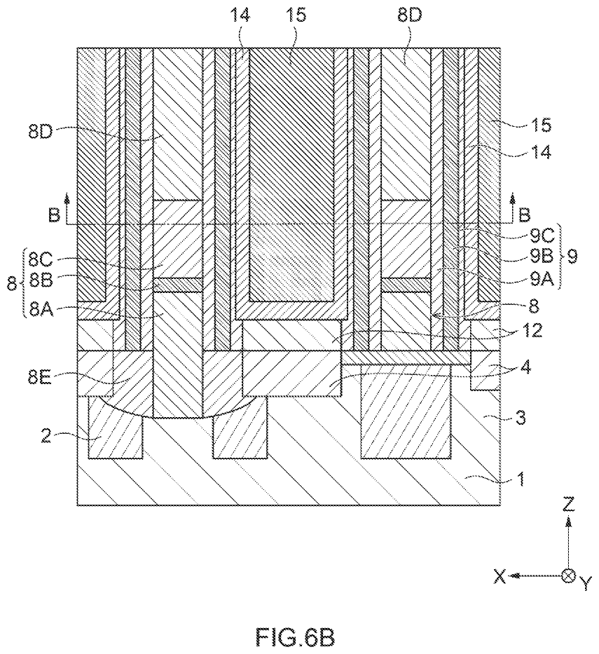

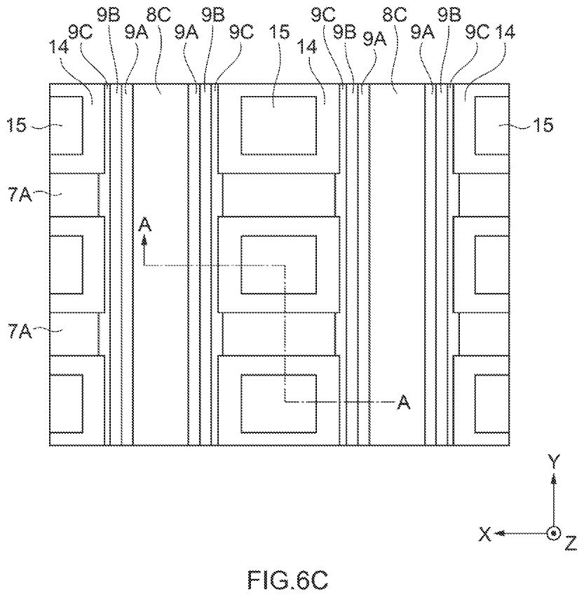

Next, as shown in FIGS. 6A, 6B and 6C, the under-cell-contact conductive portion 12 is formed on the first conductive portion 4. The under-cell-conduct conductive portion 12 contains a conductive material, for example, cobalt silicide (CoSi). The under-cell-contact conductive portion 12 is formed by the following steps. A film of cobalt and silicon is formed on the first conductive portion 4. Subsequently, a heat treatment is performed to form cobalt silicide. Thereafter, unreacted cobalt and silicon are removed by etching. Through the above steps, the under-cell-contact conductive portion 12 is formed.

Next, the barrier metal 14 and the conductive plug 15 are formed. The barrier metal 14 and conductive plug 15 are formed by the following steps. A conductive material which will serve as the barrier metal 14 and a conductive material which will serve as the conductive plug 15 are formed so as to cover the upper surface of the under-cell-contact conductive portion 12, the side surface of the third bit-line sidewall insulating portion 9C, and the upper surfaces of the first bit-line sidewall insulating portion 9A, the second bit-line sidewall insulating portion 9B, and the third bit-line sidewall insulating portion 9C. The barrier metal 14 includes, for example, a laminated film of titanium and titanium nitride. The conductive plug 15 contains, for example, tungsten. The conductive materials that will serve as the barrier metal 14 and the conductive plug 15 form films, for example, by a known chemical vapor deposition (CVD) technique. Next, a known chemical mechanical polishing (CMP) technique is performed to polish and remove titanium, titan nitride and tungsten to the extent that the upper surfaces of the first bit-line sidewall insulating portion 9A, the second bit-line sidewall insulating portion 9B, and the third bit-line sidewall insulating portion 9C are exposed. This flattens these upper surfaces. Through the steps described above, the under-cell-contact conductive portion 12, the barrier metal 14 and the conductive plug 15 are embedded in the recess portion 10.

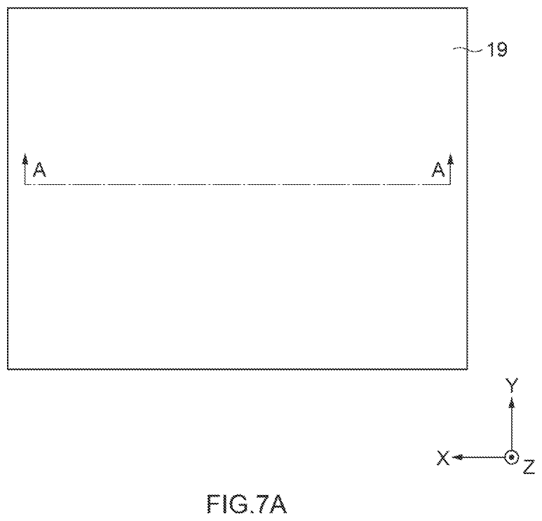

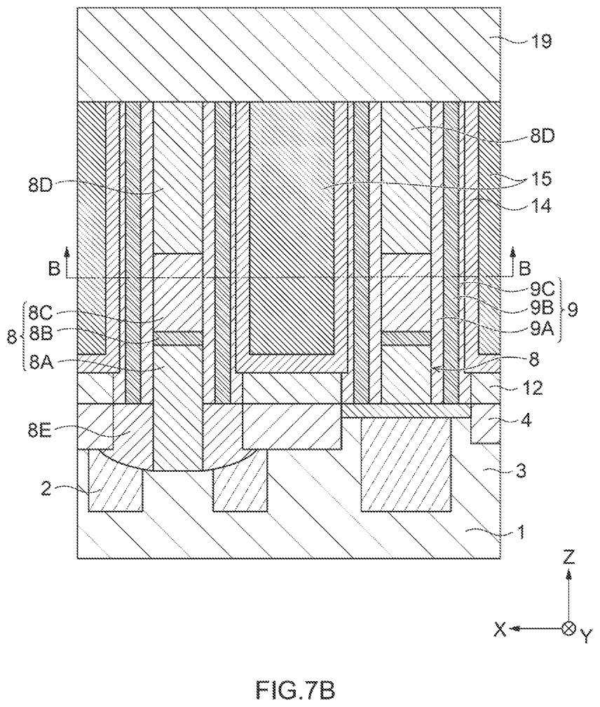

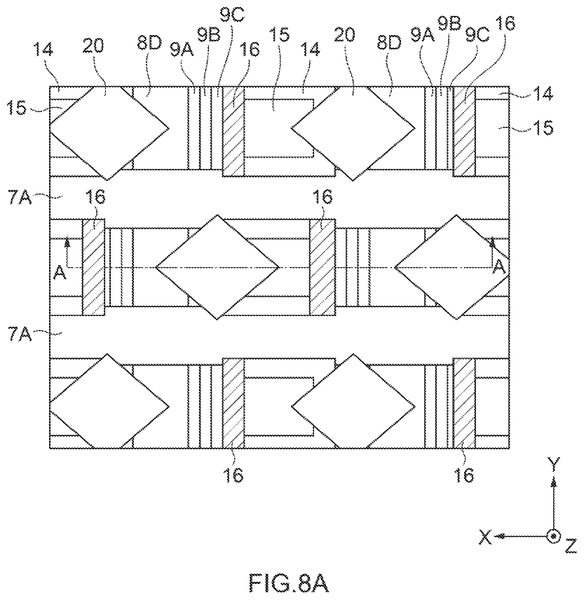

Next, as shown in FIGS. 7A and 7B, a film of a conductive material 19 which will serve as the pad conductive portion 20 is formed so as to cover the upper surfaces of the first bit-line sidewall insulating portion 9A, the second bit-line sidewall insulating portion 9B, the third bit-line sidewall insulating portion 9C, the barrier metal 14 and the conductive plug 15. The conductive material 19 contains, for example, tungsten. The film of the conductive material 19 is formed, for example, by using the known CVD technique. Note that the cross-sectional view taken along line B-B in FIG. 7B is the same as that in FIG. 6C.

Next, as shown in FIGS. 8A, 8B and 8C, known lithographic technique and anisotropic dry etching technique are carried out to pattern the conductive material 19 and form the pad conductive portions 20. This etching causes the recess portions 21 to be formed at portions which are not covered with the pad conductive portions 20. Further, by using the pad conductive portion 20 as a mask, the barrier metal 14 which is not covered with the pad conductive portion 20 is selectively etched. This etching is performed under the condition that the etching rate of titanium/titanium nitride is high and the etching rates of the other substances are low. As a result, the air-gap 16 is formed in a portion from which the barrier metal 14 has been removed. The air-gaps 16 is formed at a part of the portion which is not covered with the pad conductive portion 20. No air-gap 16 is formed on the opposite side in the X direction of the air-gap 16 with respect to the bit-line 8. The barrier metal 14 remains at the bottom portion of the air-gap 16. The pad conductive portion 20 is arranged so as to connect to one end portions of the barrier metal 14 and the conductive plug 15 as shown in FIG. 8A. The pad conductive portions 20 are arranged to be staggered on the left and right sides of the bit-line 8 with the bit-line upper insulating portion 8D, that is, the bit-line 8 as the center.

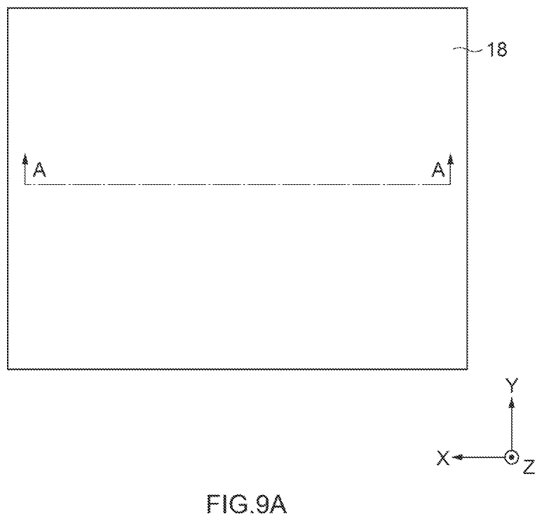

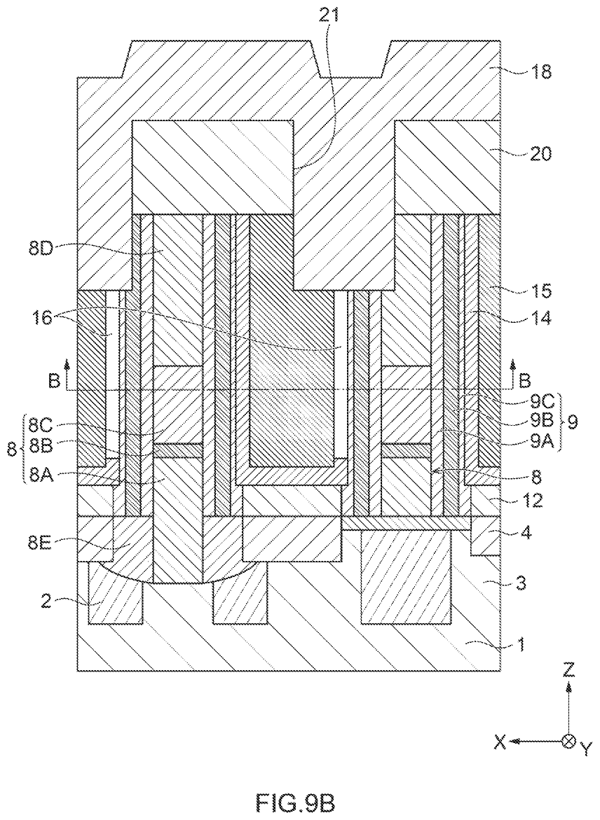

Next, as shown in FIGS. 9A and 8B, the first interlayer insulating film 18 is formed so as to cover the upper and side surfaces of the pad conductive portion 20 and the inner surface of the recess portion 21. The film formation of the first interlayer insulating film 18 is performed under a low coverage condition. As a result, the first interlayer insulating film 18 is not formed inside the air-gap 16, and the air-gap 16 includes a hollow having a top portion blocked by the first interlayer insulating film 18.

Next, as shown in FIG. 2, a known CMP technique is carried out to polish and remove the first interlayer insulating film 18 to the extent that the surface of the pad conductive portion 20 is exposed. This step flattens the upper surface. Next, the cell capacitors 25 each including the capacitor lower electrode 26, the capacitor insulating film 28 and the capacitor upper electrode 30 are formed. A beam portion 32 is formed between the capacitor lower electrodes 26. The beams 32 can enhance the mechanical strength during the processing. Next, by using the known CVD technique, films of the first top cell conductive portion 36 and the second top cell conductive portion 38 are formed so as to cover the upper surfaces of the capacitor upper electrodes 30. Through the above steps, the structure shown in FIG. 2 is formed.

Through the above steps, the air-gap 16 can be formed between the bit-line 8 and the conductive plug 15. The presence of the air-gap 16 reduces the capacitance value between the bit-line 8 and the conductive plug 15. As a result, the bit-line capacitance is reduced, so that the operating speed of the semiconductor device according to the present embodiment can be increased.

As described above, the semiconductor device according to the present embodiment has been described by exemplifying DRAM, but this is an example, and has no intention to limit the semiconductor device to DRAM. The present embodiment may be applied to memory devices other than DRAM, such as a static random access memory (SRAM), a flash memory, an erasable programmable read only memory (EPROM), a magneto-resistive random access memory (MRAM), a phase-change memory. Further, with respect to the semiconductor devices according to the above embodiments, the embodiments are applicable to devices other than memories, for example, a microprocessor, a logic IC such as an application specific integrated circuit (ASIC), and the like.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
first and second conductive pillars in a first layer, each of the first and second conductive pillars including a conductive plug of which a first side surface is covered with a barrier material and a second side surface opposed to the first side surface is coupled to an air-gap free from the barrier material;
a wiring in the first layer, the wiring arranged between the first conductive pillar and the second conductive pillar such that a first side surface of the wiring faces the barrier material of the first conductive pillar and a second side surface opposed to the first side surface of the wiring faces to the air-gap of the second conductive pillar.

2. The apparatus of claim 1, wherein the barrier material of each of the first and second conductive pillars covers all side surfaces of the conductive plug other than the second side surface.

3. The apparatus of claim 2, wherein the barrier material of each of the first and second conductive pillars further covers a bottom surface of the conductive pillar.

4. The apparatus of claim 1, further comprising first and second insulating pillars in a second layer above the first layer;
wherein each of the first and second insulating pillars is at least in part on the air-gap of the corresponding one of the first and second conductive pillars.

5. The apparatus of claim 1, further comprising:
first and second additional conductive pillars in a second layer above the first layer, each of the first and second additional conductive pillars being, at least in part, on the barrier material of a corresponding one of the first and second conductive pillars; and
first and second cell capacitors in a third layer above the second layer, the first and second cell capacitors coupled respectively to the first and second additional conductive pillars.

6. The apparatus of claim 1, wherein the conductive plug comprises tungsten.

7. The apparatus of claim 1, wherein the barrier material comprises titanium and titanium nitride.

8. The apparatus of claim 1, wherein said apparatus is a Dynamic Random Access Memory (DRAM) and the wiring is a bit-line.

9. An apparatus comprising:
a cell contact;
a bit-line; and
an insulating film having an air-gap between the cell contact and the bit-line.

10. The apparatus of claim 9, further comprising an additional cell contact arranged such that the bit-line is between the cell contact and the additional cell contact;
wherein the insulating film has no air-gap between the additional cell contact and the bit-line.

11. The apparatus of claim 9, wherein the insulating film covers both side surface of the bit-line.

12. The apparatus of claim 9, wherein the insulating film is a laminated film comprising a plurality of insulating films.

13. The apparatus of claim 9, wherein the cell contact comprises a conductive plug of which a first side surface is covered with a barrier material and a second side surface opposed to the first side surface is coupled to the air-gap free from the barrier material.

14. The apparatus of claim 13, wherein the conductive plug comprises tungsten.

15. The apparatus of claim 13, wherein the barrier material comprises titanium and titanium nitride.

16. The apparatus of claim 9, wherein said apparatus is a Dynamic Random Access Memory (DRAM).

17. The apparatus of claim 9, further comprising a cell capacitor;
wherein the cell capacitor is electrically connected to the cell contact.

18. A method comprising:
forming a wiring extending in a first direction and having sidewall insulating films on both sidewalls thereof;
forming a pillar electrode adjacent to the wiring in a second direction perpendicular to the first direction, the pillar electrode comprising a conductive plug and a barrier metal covering a lower surface and a side surface of the conductive plug;
forming a pad electrode over a portion of the barrier metal of one side of the pillar electrode opposite to the wiring;
selectively etching the barrier metal between the wiring and the pillar electrode using the pad electrode as a mask.

19. The method of claim 18, wherein the conductive plug comprises tungsten; and
wherein the barrier metal comprises titanium and titanium nitride.

20. The method of claim 18, wherein the method is a DRAM manufacturing method and the wiring is a bit-line of the DRAM.
